(19) United States
(12) Patent Application Publication
(10) Pub. No.: US 2026/0329113 A1
(43) Pub. Date: Oct. 22, 2026

(54) WAVELENGTH TUNABLE OPTICAL ELEMENT WITH TEMPERATURE CONTROL USING BOTH THERMOELECTRIC ELEMENT AND HEATER

(71) Applicant: PHOVEL Co, Ltd., Daejeon (KR)

(72) Inventor: Jeong Soo KIM, Sejong-si (KR)

(21) Appl. No.: 19/184,858

(22) Filed: Apr. 21, 2025

(51) Int. Cl. G02F 1/01

(52) U.S. Cl. CPC G02F 1/0147; G02F 1/0121

(57) ABSTRACT

A wavelength tunable optical element with temperature control using both a thermoelectric element and a heater according to the present disclosure includes a thermoelectric element with temperature control; and a modulator-integrated semiconductor laser which is provided above the thermoelectric element, has a light source equipped with a heater on one side thereof and a modulator on the other side thereof, and in which a wavelength generated from the light source varies using both the thermoelectric element and the heater.

### BACKGROUND

### 1. Field

The present disclosure relates to a wavelength tunable optical element with temperature control using both a thermoelectric element and a heater.

### 2. Description of Related Art

Currently, light-emitting elements used in optical communications are used in the form of direct modulation type semiconductor lasers or modulator-integrated semiconductor lasers. In both cases of direct modulation type semiconductor lasers and modulator-integrated semiconductor lasers, a distributed feedback (DFB)-laser diode (LD) with a grating is used as a laser oscillation light source, and in the case of direct modulation type, a modulation signal is created by directly modulating the current supplied to the DFB-LD, and a modulator-integrated semiconductor laser (electro-absorption modulator integrated DFB-LD: EML) operates the DFB-LD continuously and performs optical modulation by mounting an optical modulator on the optical output section of the DFB-LD.

An oscillation wavelength of this DFB-LD changes according to temperature change with a slope of 0.1 nm/°C (for example) depending on the operating temperature change. Currently, optical communications are using a method for increasing transmission capacity of optical communications by utilizing wavelength division multiplexing, and are adopting a dense wavelength division multiplexing (DWDM) method in which a wavelength interval of a channel is 100 GHz (0.8 nm wavelength interval in a 1550 nm region).

Since the wavelength of the DFB-LD changes at 0.1 nm/°C, in order to stabilize the wavelength of the semiconductor light source, it is necessary to maintain the temperature of the semiconductor laser or the temperature of the modulator-integrated semiconductor laser (EML) constant regardless of the change in the external environmental temperature. To this end, the structure of the DFB-LD mounted on the thermoelectric element or the EML mounted on the thermoelectric element is used as a semiconductor light source for the DWDM. In particular, a wavelength-tunable DFB-LD that changes the operating temperature of the DFB-LD by changing the temperature of the thermoelectric element and changes an oscillation channel is widely used. However, in the case of EML, since the temperature characteristics of the absorption wavelength that should be in the modulator region are different from the temperature characteristics of the DFB-LD oscillation wavelength inside the EML, it is very difficult to change the EML oscillation wavelength by changing the temperature of the thermoelectric element in the EML while maintaining the modulation characteristics.

### SUMMARY

The present disclosure provides a wavelength tunable optical element capable of minimizing power consumption of a thermoelectric element while minimizing a change in absorption characteristics of a modulator due to a temperature change in a DFB-LD by simultaneously using a thermoelectric element and a heater.

According to an aspect of the present disclosure, a wavelength tunable optical element with temperature control using both a thermoelectric element and a heater includes: a thermoelectric element with temperature control; and a modulator-integrated semiconductor laser which is provided above the thermoelectric element, has a light source equipped with a heater on one side thereof and a modulator on the other side thereof, and in which a wavelength generated from the light source varies using both the thermoelectric element and the heater.

A thermoelectric element-changing temperature by the thermoelectric element may change the wavelength of the light source and the modulator, and a heater-changing temperature by the heater may change only the wavelength of the light source.

The light source-changing temperature received by the light source may be a sum of thermoelectric element-changing temperature by the thermoelectric element and heater-changing temperature by the heater.

The wavelength of the light source may change by the light source-changing temperature received by the light source, and a wavelength of a band gap of the modulator may change by the thermoelectric element-changing temperature.

The thermoelectric element-changing temperature by the thermoelectric element and the heater-changing temperature by the heater may be set to a temperature at which the wavelength of the changing light source and the wavelength of the band gap of the changing modulator become the same.

The changing wavelength of the light source may be a value obtained by multiplying the light source-changing temperature and an oscillation wavelength change rate according to the temperature of the light source, and a wavelength of the band gap according to the temperature of the modulator may be a value obtained by multiplying the thermoelectric element-changing temperature and a wavelength change rate of the band gap according to the temperature of the modulator.

The thermoelectric element-changing temperature by the thermoelectric element may be the wavelength change rate value of (the light source-changing temperature * the oscillation wavelength change rate according to the temperature of the light source/the band gap according to the temperature of the modulator), and the heater-changing temperature by the heater may be a value obtained by subtracting the thermoelectric element-changing temperature from the light source-changing temperature.

The wavelength tunable optical element may further include a control unit that calculates the thermoelectric element-changing temperature value by the thermoelectric element and the heater-changing temperature value by the heater.

The modulator-integrated semiconductor laser may include a first cladding layer that is formed above a substrate, a multiple quantum well (MQW) active layer formed above the first cladding layer over the entirety of a light source region and a modulator region, a second cladding layer formed above the MQW active layer, and a heater.

The optical element may further include a first electrode formed above the second cladding layer and an insulating film formed above the first electrode, and the heater may be formed above the insulating film.

The second cladding layer may be formed so that a height of the cladding layer formed in the light source region and the modulator region is higher than that of the cladding layer formed between the light source region and the modulator region.

The optical element may further include a second electrode formed above the second cladding layer in the modulator region.

### BRIEF DESCRIPTION OF DRAWINGS

FIGS. 1 and 2 are diagrams for describing a structure of a wavelength tunable optical element according to an embodiment of the present disclosure.

FIG. 3 is a diagram for describing photoluminescence and light absorption characteristics in a Fabry-Perot (FP) structure.

FIG. 4 is a diagram for describing the photoluminescence and light absorption characteristics of the DFB-LD.

FIG. 5 is a diagram for describing light absorbance according to a voltage of a modulator by a quantum confined stark effect (QCSE).

FIGS. 6 and 7 are diagrams for describing a change in characteristics of the modulator when an oscillation wavelength increases by 3 nm using a thermoelectric element in an EML element.

FIGS. 8 and 9 are diagrams for describing the characteristics of the modulator when the oscillation wavelength increases by 3 nm using a heater in the EML element.

FIGS. 10 and 11 are diagrams for describing characteristics of a modulator when an oscillation wavelength increases by 3 nm by changing temperatures of a heater and a thermoelectric element in an EML element according to a first embodiment.

FIG. 12 is a graph of power consumption of a thermoelectric element according to a heat value in an optical element on the thermoelectric element according to the first embodiment of FIGS. 10 and 11.

FIGS. 13 and 14 are diagrams for describing characteristics of a modulator when an oscillation wavelength increases by 3 nm by changing temperatures of a heater and a thermoelectric element in an EML element according to a second embodiment.

FIG. 15 is a graph of power consumption of a thermoelectric element according to a heat value in an optical element on the thermoelectric element according to the second embodiment of FIGS. 13 and 14.

### DETAILED DESCRIPTION

Hereinafter, detailed contents for carrying out the present disclosure will be described in detail with reference to the accompanying drawings.

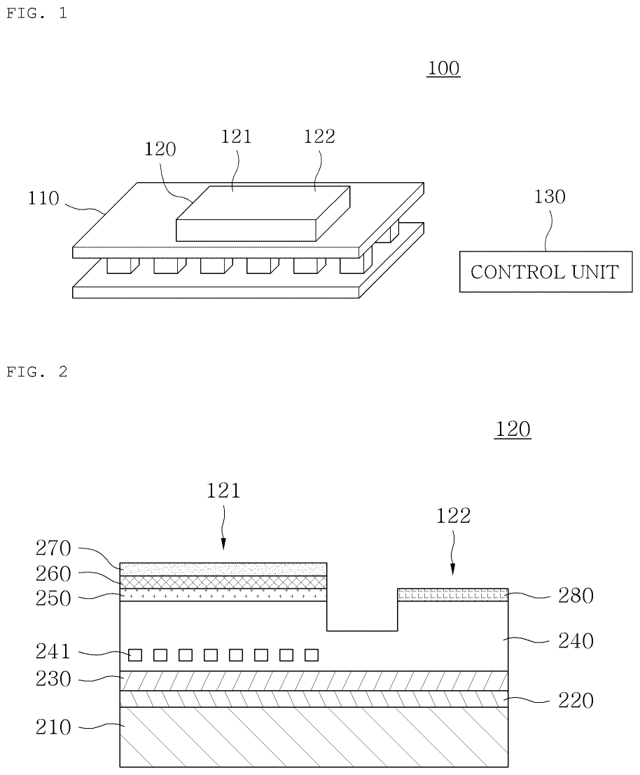

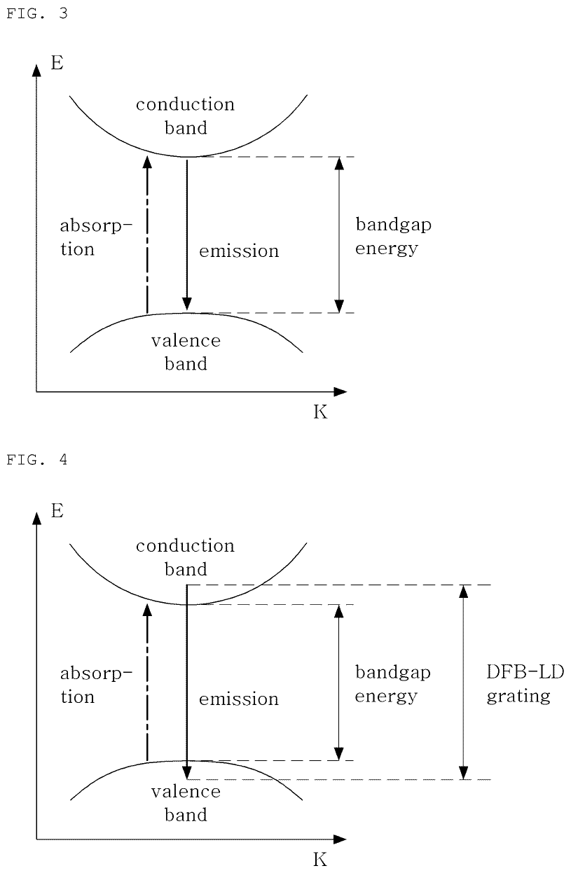

FIGS. 1 and 2 are diagrams for describing a structure of a wavelength tunable optical element according to an embodiment of the present disclosure.

FIG. 1 is a diagram of a wavelength tunable optical element in which a modulator-integrated semiconductor laser (EML) is mounted on a thermoelectric element, and FIG. 2 is a diagram of cross-sectional structure of a modulator.

Referring to FIG. 1, a wavelength tunable optical element 100 may include a thermoelectric element 110 and a modulator-integrated semiconductor laser (EML) 120 provided above the thermoelectric element 110.

The thermoelectric element 110 may control a temperature according to a control signal.

The modulator-integrated semiconductor laser (EML) may include a light source 121 and a modulator 122. For example, the modulator 122 may be an electro-absorption modulator (EAM).

The control unit 130 may control the operation of the components formed in the wavelength tunable optical element 100. For example, the control unit 130 may control the operation of the first electrode, the second electrode, the thermoelectric element, the heater, etc., based on directly calculated data values or externally input control signals.

Referring to FIGS. 1 and 2, the modulator-integrated semiconductor laser (EML) may include a light source 121 and a modulator 122.

In the light source 121, electron movement occurs that exceeds an energy band gap of the light source between a conduction band and a valence band, and photons with a wavelength corresponding to the energy are emitted.

In the modulator 122, when the energy band gap of the modulator between the conduction band and the valence band does not change because a reverse voltage is not applied to the modulator, the energy band gap of the modulator region is larger than that of the light source region, so the light of energy emitted from the light source is not absorbed by the modulator and passes through as it is.

When the reverse voltage is applied to the modulator, the energy band gap of the modulator is reduced by a quantum confined stark effect (QCSE) (for example, it may be the same as the energy band gap of the light source), and in this case, the modulator region absorbs the light emitted from the light source well and exhibits the basic characteristics (functions) of the modulator. In this way, it may be confirmed that the modulator operates well when the energy band gap of the modulator region is larger than that of the light source region.

The modulator-integrated semiconductor laser (EML) may include a substrate 210, a first cladding layer 210, an MQW active layer 230, a second cladding layer 240, a first electrode 250, an insulating film 260, a heater 270, and a second electrode 280.

The light source included in the modulator-integrated semiconductor laser (EML) may have a DFB-LD or DBR-LD structure.

The thermoelectric element-changing temperature by the thermoelectric element changes the wavelength of the light source and the modulator, and the heater-changing temperature by the heater changes only the wavelength of the light source.

The first cladding layer 220 may be formed above the substrate 210.

The MQW active layer 230 may be formed above the first cladding layer 220.

The second cladding layer 240 may be formed above the MQW active layer 230. The second cladding layer 240 may have a height that is almost similar to that of the cladding layer formed on the light source 121 and the modulator 122, and the cladding layer formed between the light source 121 and the modulator 122 may be formed lower than the cladding layer formed on the light source 121 and the modulator 122.

The second cladding layer 240 may further include a grating part 241 on a lower of the inside thereof. The wavelength of the light source is determined by the grating part 241, and the wavelength of the light source changes depending on the temperature applied to the grating part 241.

In another embodiment, the grating part 241 may be formed above the first cladding layer 220 rather than the second cladding layer 240.

The first electrode 250 may be formed above the second cladding layer 240 in the region where the light source 121 is present.

The first electrode 250 is a P electrode, and electrons in the electrode move to the MQW active layer 230 through the second cladding layer 240.

The insulating film 260 may be formed between the first electrode 250 and the heater 270. The insulating film 260 may insulate between the first electrode 250 and the heater 270.

The heater 270 generates heat, and the heat generated by the thermoelectric element and the heater 270 is transmitted to the grating part 241.

The second electrode 280 may be formed above the second cladding layer 240 in the region where the modulator 122 is present.

The second electrode 280 is an electrode used to apply a reverse voltage to the modulator. When a reverse voltage is applied to the modulator using the second electrode 280, the energy band gap of the modulator is reduced by the quantum confined stark effect (QCSE).

Since the MQW active layer 230 is formed equally across the light source 121 and the modulator 122, the light source energy band gap of the light source 121 region and the modulator energy band gap of the modulator 122 region may be the same.

The control unit 130 may generate the light source-changing temperature received by the light source by using both (simultaneously) the thermoelectric element 110 and the heater 270 to generate a temperature change corresponding to the light source-changing temperature (e.g., 30 °C) received by the light source. For example, the control unit 130 may generate the light source-changing temperature received by the light source by calculating the sum of the thermoelectric element-changing temperature (e.g., 10 °C) by the thermoelectric element 110 and the heater-changing temperature (e.g., 20 °C) by the heater 270.

For a specific example, the thermoelectric element-changing temperature value by the thermoelectric element 110 and the heater-changing temperature value by the heater 270 may be calculated based on the light source-changing temperature (e.g., 30 °C) received by the light source. For example, the control unit 130 may calculate the thermoelectric element-changing temperature value by the thermoelectric element and the heater-changing temperature value by the heater using Equations 1 and 2 below. The numerical values below are for description only and may be set in various ways according to various environmental changes.

Light source-changing temperature ‘T’ received by light source*oscillation wavelength change rate ‘X’ according to temperature of light source =thermoelectric element-changing temperature ‘A’ changed by thermoelectric element*wavelength change rate Y′ of band gap according to temperature of modulator. Equation 1

Heater-changing temperature ‘B’ changed by the heater=T°C-A°C Equation 2

For example, it may be assumed that the light source-changing temperature received by the light source increases by 30 °C, the oscillation wavelength change rate ‘X’ according to the temperature of the light source: 0.1 nm/°C, the wavelength change rate of the band gap according to the temperature of the modulator ‘Y’: 0.5 nm/°C, and the light source-changing temperature received by the light source: T°C.

In this case, according to Equation 1, the thermoelectric element-changing temperature ‘A’ may be calculated as 6 °C through 30 °C*0.1 nm/°C =A*0.5 nm/°C.

According to Equation 2, the heater-changing temperature ‘B’ changed by the heater may be calculated as 30 °C-6 °C=24 °C

The specific details related to this will be described in detail in the diagrams below.

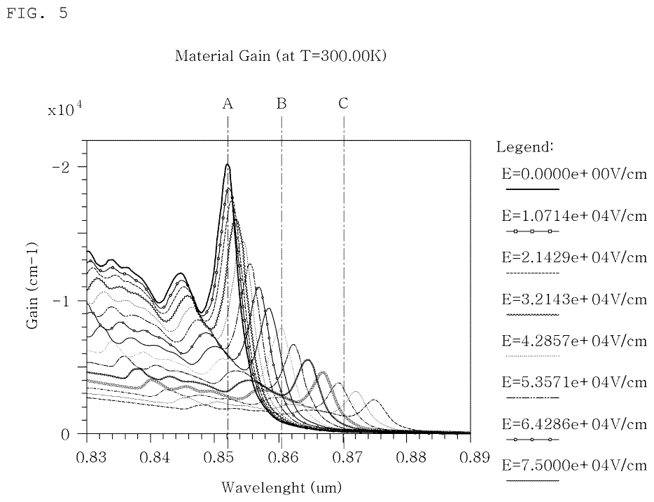

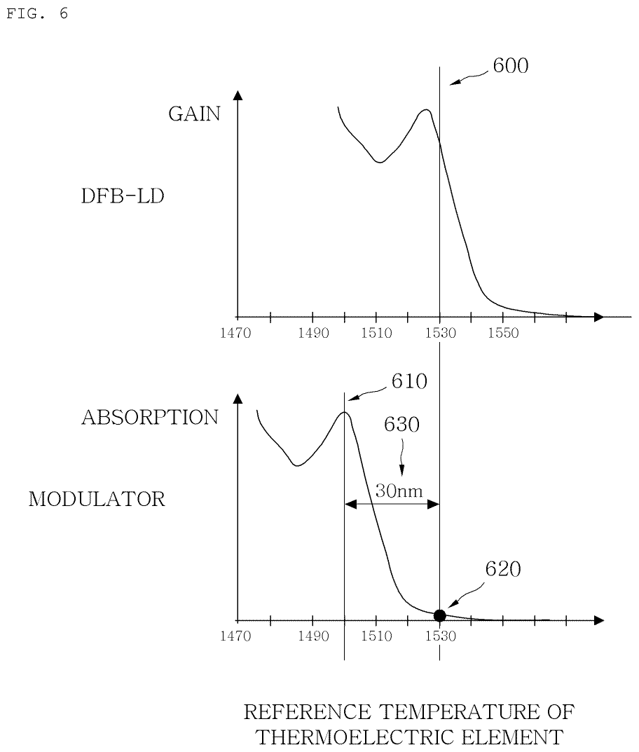

FIG. 3 is a diagram for describing photoluminescence and light absorption characteristics in a Fabry-Perot (FP) structure, and FIG. 4 is a diagram for describing photoluminescence and light absorption characteristics of the DFB-LD.

Referring to FIG. 3, the photoluminescence and light absorption processes in a general Fabry-Perot (FP) structure are shown. When there is no grating in the laser diode structure, the photoluminescence or light absorption occurs at the energy band edge where the gain or absorption is maximum.

On the other hand, referring to FIG. 4, in the DFB-LD, light is emitted at a wavelength determined by a grating and a semiconductor refractive index regardless of the band gap of the semiconductor material.

However, when the oscillation wavelength in the DFB-LD is far from a center of a gain, the desired oscillation wavelength may not be obtained. Therefore, in the case of the DFB-LD, the oscillation wavelength of the DFB-LD should be set near the band gap where the gain is maximized.

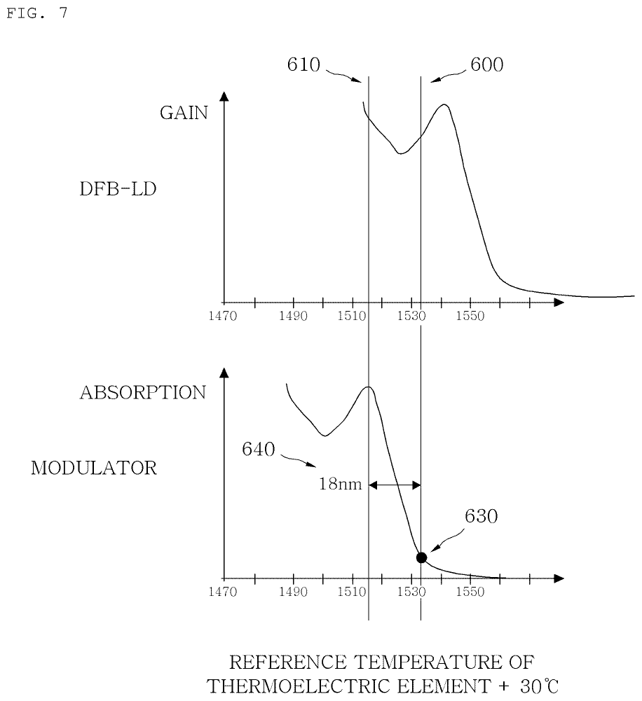

FIG. 5 is a diagram for describing the light absorbance according to the voltage of the modulator by the quantum confined stark effect (QCSE).

Referring to FIG. 5, line A shows an absorption spectrum of light when no voltage is applied to the modulator. Line A corresponds to the band gap of the modulator 121 material.

When light having a wavelength corresponding to line B is incident on the modulator, the absorbance when no voltage is applied to the modulator (E=0.0000e+00V/cm) becomes point B1. When a voltage is applied to the modulator, the absorbance gradually changes to point B2.

Accordingly, when no voltage is applied to the modulator based on line B, the absorbance corresponds to point B1, which has very low absorbance, so light easily transmits through the modulator. When a voltage is applied to the modulator, the absorbance increases to point B2, which has relatively higher absorbance than point B1, so light is effectively blocked and does not transmit through the modulator well. In this way, the absorbance changes as a voltage is applied, and the amount of light transmitted through the modulator changes accordingly.

In FIG. 5, when light with a wavelength of C is incident on the modulator, the absorbance of the light changes from point C1 to point C2 even when a voltage is applied to the modulator, so the range of change is small, making it difficult to effectively transmit/absorb light. Therefore, the band gap of the modulator should maintain an appropriate wavelength interval for the wavelength of light generated from the DFB-LD.

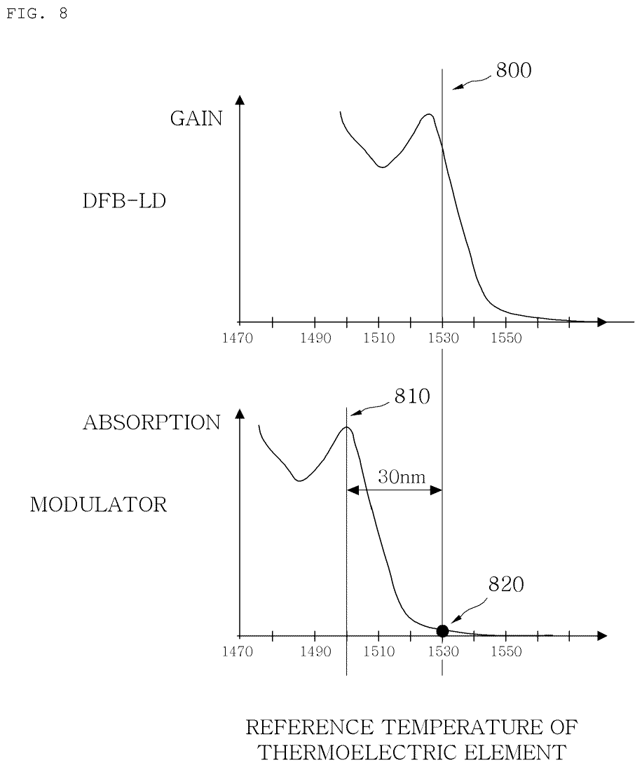

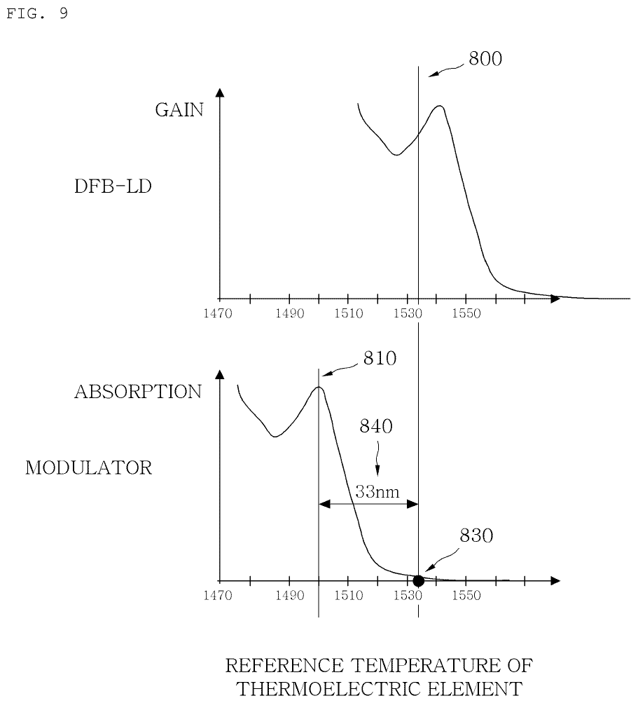

FIGS. 6 and 7 are diagrams for describing a change in characteristics of the modulator when the oscillation wavelength increases by 3 nm using the thermoelectric element in the EML element.

In the case of the EML, (1) the oscillation wavelength change rate according to the temperature of the light source region and (2) the wavelength change rate of the band gap according to the temperature of the modulator region are different from each other. Accordingly, when simply changing a specific temperature (e.g., 30 °C) to change the wavelength (e.g., change by 3 nm), a problem may arise where the desired modulation characteristics are not obtained due to the difference in the modulation characteristics of the DFB-LD and the modulator. In other words, when the operating temperature of the modulator changes, the band gap changes regardless of the voltage of the modulator, making it impossible to properly implement the modulation characteristics.

Since the characteristics of the DFB-LD and the modulator of the EML element are sensitive to the operating temperature, the EML element is usually stabilized by using the thermoelectric element (TEC), which is a device that may maintain the temperature of the element constant regardless of the external environment.

The wavelength of the DFB-LD is utilized as a wavelength-tunable laser by taking advantage of the characteristics that the wavelength increases with increasing temperature. In other words, when the operating temperature of DFB-LD increases by approximately 8 °C, the oscillation wavelength of DFB-LD increases by approximately 0.8 nm, and is used as a light source for other channels of DWDM with 0.8 nm intervals. Currently, NG-PON 2 and other DWDM light sources are using 4-channel wavelength-tunable light sources with 0.8 nm intervals, and the temperature of these light sources increases by approximately 0 °C/8 °C/16 °C/24 °C from the reference temperature to be used as a 4-channel wavelength-tunable light source. Likewise, an EML light source may also be used as wavelength-tunable EML optical element by changing the operating temperature of the thermoelectric element that determines the temperature of the EML element. However, when the EML element is used as a wavelength-tunable laser light source corresponding to various oscillation wavelengths by simply changing the temperature of the thermoelectric element, various problems may occur.

Referring to FIG. 6, the graph shows the case where the temperature of the thermoelectric element is the “reference temperature”, the upper graph shows a wavelength-gain curve of a DFB-LD region, and the lower graph shows a wavelength-absorption curve of a modulator region.

For example, the oscillation wavelength of the DFB-LD shows a change characteristic that increases by about 0.1 nm/°C, and the wavelength of the band gap of the modulator shows a change characteristic that increases by about 0.5 nm/°C. The above numerical values are set to help understanding, and various numerical values may be applied. The temperature change of the thermoelectric element affects both the DFB-LD and the modulator.

When the temperature of the thermoelectric element is the “reference temperature”, the oscillation wavelength 600 of the DFB-LD is 1530 nm, and the wavelength may be selected by the grating. When a bias voltage is “0”, the absorption value in the modulator at the wavelength of 1530 nm may have a first absorption value 620. The oscillation wavelength 600 of the DFB-LD at the “reference temperature” is 1530 nm, and a peak wavelength 610 in the absorption spectrum of the modulator is 1500 nm. Accordingly, the difference between the oscillation wavelength 600 of the DFB-LD and the peak wavelength 610 of the modulator is 30 nm (=1530 nm−1500 nm).

Referring to FIG. 7, when the temperature of the thermoelectric element is “reference temperature+30 °C”, the heater is not used (‘temperature increase by heater 0 °C’), and only the temperature of the thermoelectric element increases by 30 °C.

As the temperature increases by 30 °C, the oscillation wavelength 600 of the DFB-LD increases by 30 °C*0.1 nm/°C=3 nm, and thus, becomes 1533 nm. In addition, the wavelength of the band gap of the modulator (‘absorption spectrum’) increases by 30 °C*0.5 nm/°C=15 nm, so that the peak wavelength 610 of the modulator becomes 1515 nm.

The absorption value in the modulator at the wavelength of 1533 nm is the second absorption value 630, which is greater than the first absorption value 620 of FIG. 6. In addition, the difference between the DFB-LD oscillation wavelength 600 and the peak wavelength 610 of the modulator is reduced to 18 nm (640) (=1533 nm−1515 nm) compared to FIG. 6.

Accordingly, when the temperature increases using the thermoelectric element, the absorbance of the modulator increases significantly (the second absorption value is greater than the first absorption value), so the amount of light passing through the modulator decreases, and as the difference between the DFB-LD oscillation wavelength and the peak wavelength of the modulator is small, the problem of deteriorating the characteristics of the modulator occurs.

In the description of the present disclosure, the characteristics of the EML element are described when the reference temperature is set to a low temperature and the temperature increases. However, when the basic operating principle of the present disclosure is in operation, setting the reference temperature to a high temperature and changing the wavelength to a short wavelength fundamentally operate the same mechanism of the band gap change and the DFB-LD wavelength shift due to the temperature increase and decrease. The reference temperature is set to a low temperature because it is an arbitrary direction for the convenience of description, so the location of the reference temperature, the direction of wavelength movement, etc., may be arbitrarily selected and used by users of the present disclosure.

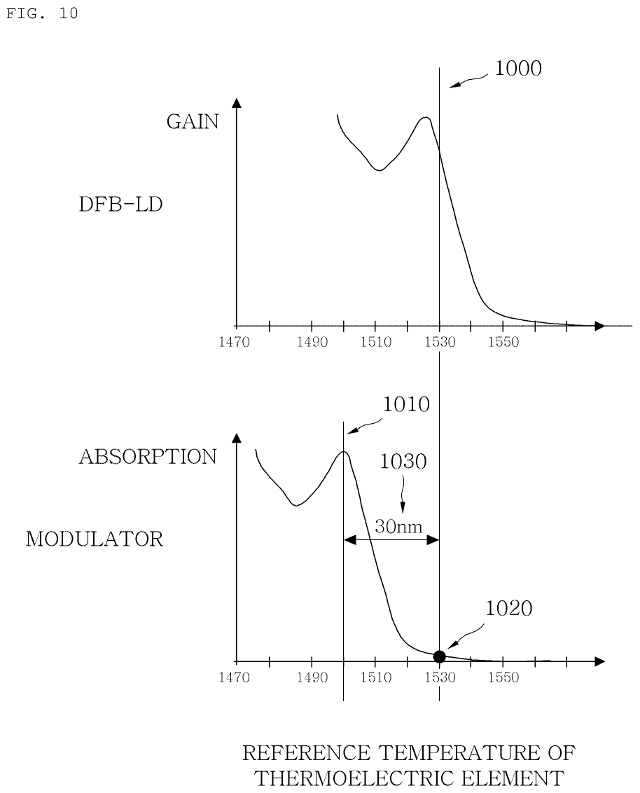

FIGS. 8 and 9 are diagrams for describing the characteristics of the modulator when the oscillation wavelength increases by 3 nm using the heater in the EML element.

Referring to FIG. 8, the graph shows the case where the temperature of the thermoelectric element is the “reference temperature”, the upper graph shows a wavelength-gain curve of a DFB-LD region, and the lower graph shows a wavelength-absorption curve of a modulator region.

When the temperature of the thermoelectric element is the “reference temperature”, the oscillation wavelength 800 of the DFB-LD is 1530 nm, and the wavelength may be selected by the grating. When a bias voltage is “0”, the absorption value in the modulator at the wavelength of 1530 nm may have a first absorption value 820. The oscillation wavelength 600 of the DFB-LD at the “reference temperature” is 1530 nm, and a peak wavelength 810 in the absorption spectrum of the modulator is 1500 nm. Accordingly, the difference between the oscillation wavelength 800 of the DFB-LD and the peak wavelength 810 of the modulator is 30 nm (=1530 nm-1500 nm).

Referring to FIG. 9, the temperature of the thermoelectric element is maintained at the “reference temperature”, and only the heater temperature increases by 30 °C.

As the temperature increases by 30 °C, the oscillation wavelength 600 of the DFB-LD increases by 30 °C*0.1 nm/°C=3 nm, and thus, becomes 1533 nm. Since the modulator is not affected by the temperature change of the heater, the wavelength (‘absorption spectrum’) of the band gap of the modulator remains the same, and the peak wavelength becomes 1500 nm. The absorption value in the modulator at the wavelength of 1533 nm is the second absorption value 830, which is slightly greater than the first absorption value 820 of FIG. 8.

The difference between the oscillation wavelength 800 of the DFB-LD and the peak wavelength 810 of the modulator slightly increases to 33 nm 840 (=1533 nm−1500 nm). These characteristics have the advantage of being able to maintain the characteristics of the modulator well since the change in wavelength difference between the DFB-LD wavelength and the modulator band gap is relatively small in the case of FIG. 9 (‘30 nm->33 nm’) compared to the change in wavelength difference between the DFB-LD wavelength and the modulator band gap (‘30 nm->18 nm’) when the temperature of the thermoelectric element of FIG. 7 is changed. However, as will be described below, when the temperature increases using only a heater, there is a problem that the power consumption of the thermoelectric element rapidly increases since the heat generated by the heater must be removed using the thermoelectric element.

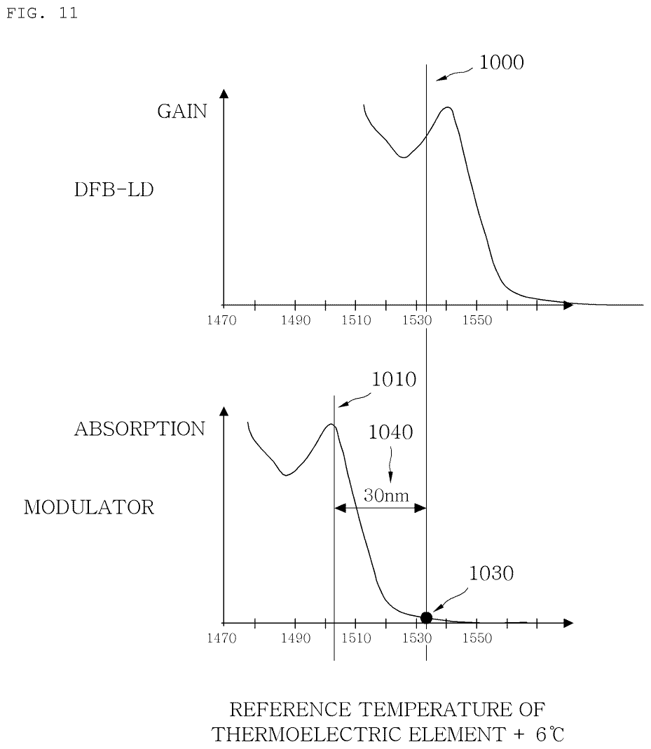

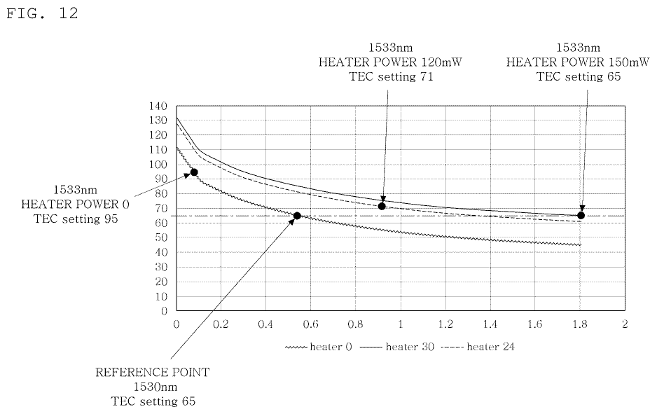

FIGS. 10 and 11 are diagrams for describing characteristics of a modulator when an oscillation wavelength increases by 3 nm by changing temperatures of a heater and a thermoelectric element in an EML element according to a first embodiment.

Referring to FIG. 10, the graph shows the case where the temperature of the thermoelectric element is the “reference temperature”, the upper graph shows a wavelength-gain curve of a DFB-LD region, and the lower graph shows a wavelength-absorption curve of a modulator region.

When the temperature of the thermoelectric element is the “reference temperature”, the oscillation wavelength 1000 of the DFB-LD is 1530 nm, and the wavelength may be selected by the grating. When a bias voltage is “0”, the absorption value in the modulator at the wavelength of 1530 nm may have a first absorption value 1020. The oscillation wavelength 800 of the DFB-LD at the “reference temperature” is 1530 nm, and the peak wavelength 810 in the absorption spectrum of the modulator is 1500 nm. Accordingly, the difference between the oscillation wavelength 800 of the DFB-LD and the peak wavelength 810 of the modulator is 30 nm (=1530 nm−1500 nm) (1030). For example, according to Equation 1, the temperature increase by the thermoelectric element may be 6 °C, and according to Equation 2, the temperature increase by the heater may be 24 °C.

Referring to FIG. 11, the temperature increase received by the DFB-LD becomes 30 °C by increasing the “reference temperature” by 6 °C using the thermoelectric element and increasing the temperature by 24 °C using the heater.

As the temperature increases by 30 °C, the oscillation wavelength 1000 of the DFB-LD increases by 30 °C*0.1 nm/°C=3 nm, and thus, becomes 1533 nm.

In the modulator, the wavelength of the band gap (‘absorption spectrum’) is affected by the temperature increased by the thermoelectric element, so the temperature increased by the thermoelectric element increases by 6 °C*0.5 nm/°C=3 nm, and a peak wavelength 1010 of the modulator becomes 1515 nm.

The absorption value in the modulator at the wavelength of 1533 nm is the second absorption value 1030, which is the same as the first absorption value 1020 of FIG. 10. This is because both the variations in the wavelength of the oscillation wavelength 1000 of the DFB-LD and the band gap of the modulator are 3 nm, showing the same absorbance as when it is the “original temperature” of FIG. 10.

The difference between the oscillation wavelength 1000 of the DFB-LD and the peak wavelength 1010 of the modulator is 30 nm (=1533 m−1503 nm). In other words, the difference between the DFB-LD oscillation wavelength 1000 and the peak wavelength 1010 of the modulator in FIG. 11 is maintained at 30 nm, which is the same as in FIG. 10.

In this way, the temperature of the thermoelectric element and the temperature of the heater are controlled so that the wavelength change of the DFB-LD (for example, 3 nm) due to the temperature increase received by the DFB-LD and the wavelength change of the band gap in the modulator (for example, 3 nm) due to the temperature increase increased by the thermoelectric element are the same, thereby preventing the occurrence of the decrease in the absorbance due to the temperature change and the modulator characteristics due to the wavelength change.

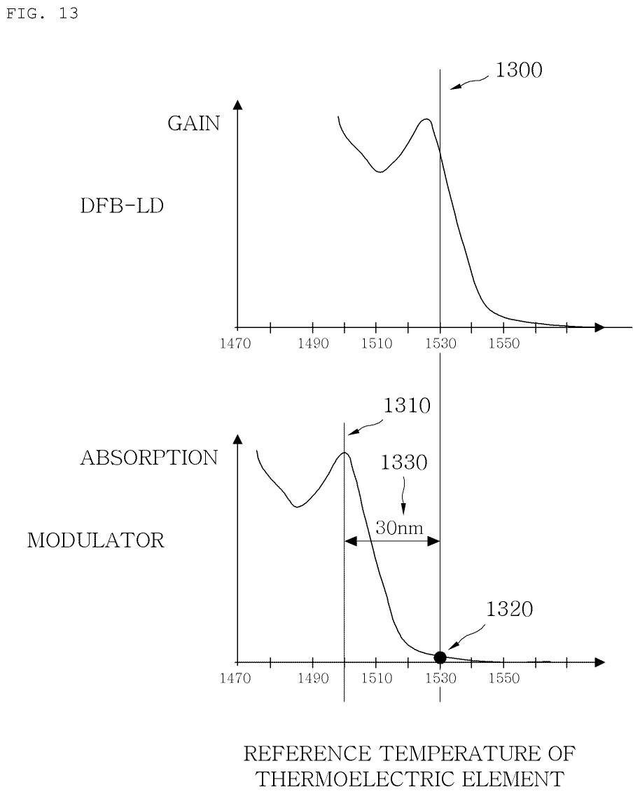

FIG. 12 is a graph of the power consumption of the thermoelectric element according to the heat generation in the optical element on the thermoelectric element according to the embodiment according to FIGS. 10 and 11. Here, the horizontal axis of the graph means the power consumption of the thermoelectric element, and the vertical axis means the temperature above the thermoelectric element.

Referring to FIG. 12, when the thermoelectric element is used in a cooling mode, the temperature of the upper portion of the thermoelectric element decreases according to the power flowing into the thermoelectric element. A temperature of an upper plate of the thermoelectric element increases according to the amount of heat added to the upper portion of the thermoelectric element, and the increased temperature decreases according to the power of the thermoelectric element.

Due to the characteristics of the thermoelectric element, the heat decreases rapidly at low power consumption (‘left region of the graph of FIG. 12’), but the heat decreases less at high power consumption (‘right region of the graph of FIG. 12’).

In the EML element with a heater, the heat generated by the power consumed by the heater causes the problem of increasing the temperature of the upper plate of the thermoelectric element. For example, when a low temperature with a short wavelength is used as a reference temperature, there are two methods for moving a short wavelength to a long wavelength: one is to increase the set temperature of the thermoelectric element, and the other is to increase the heat output of the heater while originally keeping the temperature of the thermoelectric element.

In this embodiment, when only the heater is used to raise the temperature of the DFB-LD by 30 °C, the heater requires approximately 150 mW of heat, and the thermoelectric element raises the temperature by approximately 20 °C due to the 150 mW of heat from the heater. Accordingly, the thermoelectric element should consume power to lower the increased temperature of 20 °C.

Specifically describing, it is assumed that the oscillation wavelength of the DFB-LD is 1530 nm (1530 nm, TEC setting 65 °C) at the reference temperature of the thermoelectric element that is the reference point of 65 °C, and the increased temperature received by the DFB-LD is 30 °C.

In the first case, when the temperature is raised by 30 °C using only the “thermoelectric element”, the wavelength of the DFB-LD increases by 3 nm to 1533 nm, and the temperature of the thermoelectric element becomes 95 °C (1533 nm, TEC setting 95 °C). In this case, the power consumption of the thermoelectric element was about 530 mW to maintain the reference temperature of 65 °C, but as the temperature of the thermoelectric element changes to 95 °C, the power consumption is reduced by about 450 mW as about 80 mW. However, as illustrated in FIG. 7, there is a disadvantage in that the characteristics of the modulator deteriorate because the difference between the absorbance and the DFB-LD oscillation wavelength and the peak wavelength of the modulator is reduced.

In the second case, when the temperature increases by 30 °C using only the “heater”, the wavelength of the DFB-LD increases by 3 nm to 1533 nm, the temperature of the thermoelectric element is maintained at 65 °C, and the heater power consumption is 150 mW (1533 nm, heater power consumption 150 mW, TEC setting 65 °C). In this case, the power consumption of the thermoelectric element is 1.8 W to maintain the reference temperature of 65 °C, so a total of 1950 mW is required. Therefore, the total power consumed is large, resulting in a waste of power.

In the third case, when the temperature increases by 6 °C using the “thermoelectric element” and 24 °C using the “heater”, the wavelength of the DFB-LD increases by 3 nm to 1533 nm, the heater power consumption becomes 120 mW, and the temperature of the thermoelectric element becomes 71 °C (1533 nm, heater power consumption 120 mW, TEC setting 95 °C). In this case, the power consumption of the thermoelectric element was about 530 mW to maintain the reference temperature of 65 °C, but as the temperature of the thermoelectric element changes to 71 °C, the power consumption increases by about 10 mW as about 90 mW, and the power consumption of the heater decreases from 150 mW to 130 mW. In this case, only 220 mW is required in total, so not only may the power consumption be significantly reduced compared to the second case, but the characteristics of the modulator according to the temperature change may also be maintained.

In this embodiment, as in the third case, a method is proposed to minimize the power consumption of the thermoelectric element and the heater while maintaining the characteristics of the modulator by controlling the temperature rise received by the DFB-LD by using both (or simultaneously) the thermoelectric element and the heater.

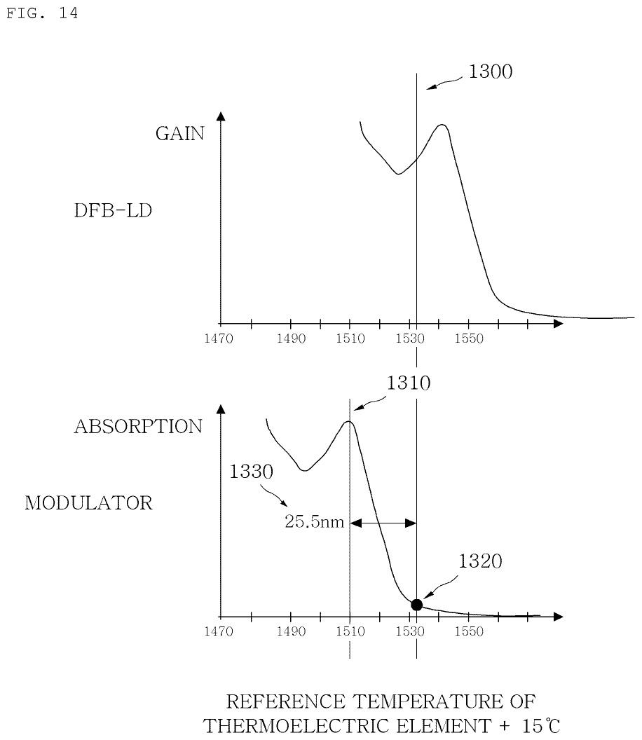

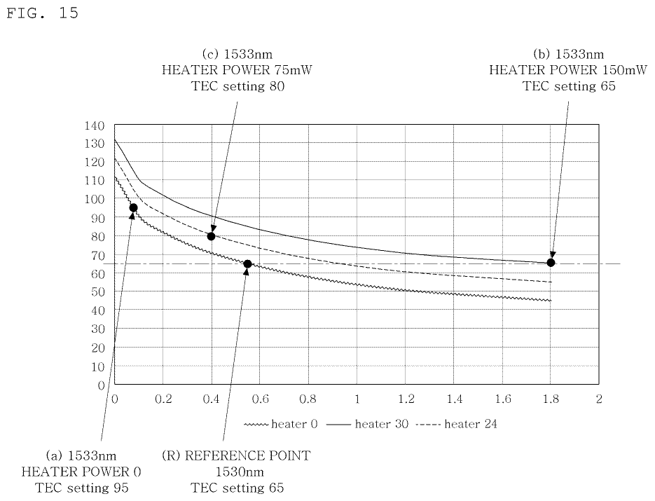

FIGS. 13 and 14 are diagrams for describing characteristics of a modulator when an oscillation wavelength is increased by 3 nm by changing temperatures of a heater and a thermoelectric element in an EML element according to a second embodiment.

Referring to FIG. 13, when the temperature of the thermoelectric element is the “reference temperature”, the oscillation wavelength 1300 of the DFB-LD is 1530 nm, and the wavelength may be selected by the grating. When a bias voltage is “0”, the absorption value in the modulator at the wavelength of 1530 nm may have a first absorption value 1320. The oscillation wavelength 1300 of the DFB-LD at the “reference temperature” is 1530 nm, and a peak wavelength 1310 in the absorption spectrum of the modulator is 1500 nm. Accordingly, the difference between the oscillation wavelength 1300 of the DFB-LD and the peak wavelength 1310 of the modulator is 30 nm (=1530 nm−1500 nm) (1330).

Referring to FIG. 14, the temperature increase received by the DFB-LD becomes 30 °C by increasing the “reference temperature” by 15 °C using the thermoelectric element and increasing the temperature by 15 °C using the heater.

As the temperature increases by 30 °C, the oscillation wavelength 1300 of the DFB-LD increases by 30 °C*0.1 nm/°C=3 nm, and thus, becomes 1533 nm.

In the modulator, the wavelength of the band gap (‘absorption spectrum’) is affected by the temperature increased by the thermoelectric element, so the temperature increased by the thermoelectric element increases by 15 °C*0.5 nm/°C=7.5 nm, and the peak wavelength 1310 of the modulator becomes 1507.5 nm.

The absorption value in the modulator at the wavelength of 1533 nm is the second absorption value 1330, which is slightly greater than the first absorption value 1320 of FIG. 13.

The difference between the DFB-LD oscillation wavelength 1000 and the peak wavelength 1010 of the modulator becomes 25.5 nm (=1533 nm−1507.5 nm), which is 4.5 nm less than the difference between the DFB-LD oscillation wavelength 1000 and the peak wavelength 1010 of the modulator in FIG. 13. In this way, the temperature of the thermoelectric element and the heater may be set so that the difference between the DFB-LD oscillation wavelength 1000 and the peak wavelength 1010 of the modulator is minimized according to the temperature change.

FIG. 15 is a graph of power consumption of a thermoelectric element according to a heat value in an optical element on the thermoelectric element according to the second embodiment of FIGS. 13 and 14.

Referring to FIG. 15, specifically describing, it is assumed that the oscillation wavelength of the DFB-LD is 1530 nm (1530 nm, TEC setting 65 °C) at the reference temperature of the thermoelectric element that is the reference point of 65 °C, and the increased temperature received by the DFB-LD is 30 °C.

When the temperature increases by 15 °C using the “thermoelectric element” and 15 °C using the “heater”, the wavelength of the DFB-LD increases by 3 nm to 1533 nm, the heater power consumption becomes 75 mW, and the temperature of the thermoelectric element becomes 80 °C (1533 nm, heater power consumption 75 mW, TEC setting 80 °C).

In this case, the power consumption of the thermoelectric element was about 530 mW to maintain the reference temperature of 65 °C, but as the temperature of the thermoelectric element changes to 80 °C, the power consumption decreases by about 130 mW to about 400 mW, and the power consumption of the heater decreases from 150 mW to 75 mW. In this case, a total of 205 mW is required, so the power consumption may be reduced more than in the case of FIG. 11, but on the other hand, the absorption value increases/the difference between the DFB-LD oscillation wavelength and the peak wavelength of the modulator decreases, so the modulator characteristics may be slightly degraded, but a rapid deterioration may be prevented.

The power consumption of the thermoelectric element and the modulation characteristics of the modulator are in a trade-off relationship. Therefore, according to the present embodiment, considering the two relationships, when the power consumption is prioritized depending on the situation, the temperature increase (for example, 20 °C) by the thermoelectric element may be set to be greater than the temperature increase (for example, 10 °C) by the heater, and conversely, when the modulation characteristics of the modulator are prioritized, the temperature increase (for example, 20 °C) by the heater may be set to be greater than the temperature increase (for example, 10 °C) by the thermoelectric element.

According to the present disclosure, in order to change the oscillation wavelength of the DFB-LD, the heater that focuses on only the DFB-LD region and the thermoelectric element that affects both the DFB-LD and the modulator are simultaneously applied to change the oscillation wavelength, so that the temperature of the modulator region is also optimized using the thermoelectric element, and at the same time, in order to increase the oscillation wavelength, the temperature increase of the DFB-LD is implemented by increasing the heat value of the heater and the temperature of the thermoelectric element, thereby minimizing the wavelength change of the DFB-LD and the power consumption of the thermoelectric element under the external environment, while maintaining the characteristics of the modulator.

The described embodiments may be configured by selectively combining all or part of each embodiment so that various modifications may be made.

In addition, it should be noted that the embodiments are for the purpose of description and not for the purpose of limitation. In addition, a person of ordinary skill in the art to which the present disclosure pertains may understand that various embodiments are possible within the scope of the technical idea of the present disclosure.

What is claimed is:

1. A wavelength tunable optical element with temperature control using both a thermoelectric element and a heater, comprising:
a thermoelectric element with temperature control; and
a modulator-integrated semiconductor laser which is provided above the thermoelectric element, has a light source equipped with a heater on one side thereof and a modulator on the other side thereof, and in which a wavelength generated from the light source varies using both the thermoelectric element and the heater.

2. The wavelength tunable optical element of claim 1, wherein a thermoelectric element-changing temperature by the thermoelectric element changes the wavelength of the light source and the modulator, and a heater-changing temperature by the heater changes only the wavelength of the light source.

3. The wavelength tunable optical element of claim 1, wherein the light source-changing temperature received by the light source is a sum of thermoelectric element-changing temperature by the thermoelectric element and heater-changing temperature by the heater.

4. The wavelength tunable optical element of claim 3, wherein the wavelength of the light source changes by the light source-changing temperature received by the light source, and a wavelength of a band gap of the modulator changes by the thermoelectric element-changing temperature.

5. The wavelength tunable optical element of claim 4, wherein the thermoelectric element-changing temperature by the thermoelectric element and the heater-changing temperature by the heater are set to a temperature at which the wavelength of the changing light source and the wavelength of the band gap of the changing modulator become the same.

6. The wavelength tunable optical element of claim 5, wherein the changing wavelength of the light source is a value obtained by multiplying the light source-changing temperature and an oscillation wavelength change rate according to the temperature of the light source, and a wavelength of the band gap according to the temperature of the modulator is a value obtained by multiplying the thermoelectric element-changing temperature and a wavelength change rate of the band gap according to the temperature of the modulator.

7. The wavelength tunable optical element of claim 6, wherein the thermoelectric element-changing temperature by the thermoelectric element is the wavelength change rate value of (the light source-changing temperature * the oscillation wavelength change rate according to the temperature of the light source/the band gap according to the temperature of the modulator), and
the heater-changing temperature by the heater is a value obtained by subtracting the thermoelectric element-changing temperature from the light source-changing temperature.

8. The wavelength tunable optical element of claim 7, further comprising:
a control unit that calculates the thermoelectric element-changing temperature value by the thermoelectric element and the heater-changing temperature value by the heater.
